(19) United States
(12) Patent Application Publication
(10) Pub. No.: US 2026/0198110 A1
(43) Pub. Date: Jul. 9, 2026

(54) IMAGE SENSOR

(71) Applicant: Samsung Electronics Co., Ltd., Suwon-si (KR)

(72) Inventors: Sunhee Yun, Suwon-si (KR); Yongjun Kim, Suwon-si (KR); Sol Yoon, Suwon-si (KR)

(21) Appl. No.: 19/264,695

(22) Filed: Jul. 9, 2025

(30) Foreign Application Priority Data
Jan. 3, 2025 (KR) 10-2025-0001201

(51) Int. Cl. H10F 39/00

(52) U.S. Cl. CPC H10F 39/802; H10F 39/8037

(57) ABSTRACT

An image sensor includes a substrate including a photoelectric conversion region and having a first surface and a second surface facing each other; and a first transistor and a second transistor positioned on the first surface of the substrate, wherein the gate electrode of the first transistor includes a first portion, a second portion, and an interlayer oxide layer positioned between the first portion and the second portion, the thickness of the gate electrode of the first transistor is 400 Å to 500 Å, and the upper surface of the gate electrode of the second transistor includes a region that is depressed in a direction toward the second surface of the substrate.

### CROSS-REFERENCE TO RELATED APPLICATION

This application claims priority to and the benefit of Korean Patent Application No. 10-2025-0001201, filed with the Korean Intellectual Property Office on Jan. 3, 2025, the entire contents of which are incorporated herein by reference.

### BACKGROUND

An image sensor is a semiconductor element that converts an optical image into an electric signal. The image sensor may be classified into a charge coupled device (CCD) type and a complementary metal oxide semiconductor (CMOS) type. The CMOS type image sensor is abbreviated as a CMOS image sensor (CIS). The CIS has a plurality of pixels arranged two-dimensionally. Each of the pixels includes a photodiode (PD). The photodiode converts incident light into an electric signal.

### SUMMARY

Some aspects of the present disclosure provides image sensors with improved noise characteristics.

An image sensor according to some implementations of the present disclosure includes a substrate including a photoelectric conversion region and having a first surface and a second surface facing each other; and a first transistor and a second transistor positioned on the first surface of the substrate, wherein the gate electrode of the first transistor includes a first portion, a second portion, and an interlayer oxide layer positioned between the first portion and the second portion, the thickness of the gate electrode of the first transistor is 400 Å to 500 Å, and the upper surface of the gate electrode of the second transistor includes a region that is depressed in a direction toward the second surface of the substrate.

An image sensor according to some implementations of the present disclosure includes a substrate including a photoelectric conversion region; and a first transistor and a second transistor positioned on the first surface of the substrate, wherein the gate electrode of the first transistor includes a first portion, a second portion, and an interlayer oxide layer positioned between the first portion and the second portion, the thickness of the gate electrode of the first transistor is 400 Å to 500 Å, the gate electrode of the second transistor includes a first portion, a second portion, and an interlayer oxide layer positioned between the first portion and the second portion, and the first portion of the gate electrode of the second transistor and a portion of the second portion are positioned below the first surface of the substrate.

An image sensor according to some implementations of the present disclosure includes a substrate comprising a photoelectric conversion region; and a first transistor and a second transistor positioned on the first surface of the substrate, wherein the gate electrode of the first transistor includes a first portion, a second portion, and an interlayer oxide layer positioned between the first portion and the second portion, the thickness of the gate electrode of the first transistor is 400 Å to 500 Å, the thickness of the first portion of the gate electrode of the first transistor is thicker than that of the second portion, the gate electrode of the second transistor includes a first portion, a second portion, and an interlayer oxide layer positioned between the first portion and the second portion, and the thickness of the first portion of the gate electrode of the second transistor is thicker than the thickness of the second portion.

A manufacturing method of an image sensor according to some implementations of the present disclosure includes forming a first gate layer on a substrate; forming a second gate layer on the first gate layer; etching the first gate layer and the second gate layer to form a gate electrode; and forming an insulation layer on the first gate layer and the second gate layer, wherein the gate electrode has a thickness of 400 Å to 500 Å.

The first gate layer may include polycrystalline silicon.

The second gate layer may include amorphous silicon.

In forming the insulation layer on the first gate layer and the second gate layer, a portion of the amorphous silicon of the second gate layer may be crystallized into polycrystalline silicon.

In forming the insulation layer on the first gate layer and the second gate layer, a portion of the amorphous silicon of the second gate layer may be oxidized into a gate oxide layer.

The thickness of the first gate layer may be 360 Å to 440 Å.

The thickness of the second gate layer may be 90 Å to 110 Å.

It may further include an interlayer oxide layer positioned between the first gate layer and the second gate layer.

The foregoing and/or other configurations, as described below, can provide image sensors with improved noise characteristics.

### BRIEF DESCRIPTION OF THE DRAWINGS

FIG. 1 is a block diagram of an example of an image sensor.

FIG. 2 is a circuit diagram of a pixel included in an example of an image sensor.

FIG. 3 is a top plan view showing an example of an image sensor.

FIG. 4 is a cross-sectional view showing a portion of a cross-section of a pixel PX of an example of an image sensor.

FIG. 5 is an enlarged view of a transistor TR of FIG. 4.

FIG. 6 is an enlarged view of a transmission transistor TX of FIG. 4.

FIG. 7 to FIG. 14 are process cross-sectional views showing an example of a manufacturing method of an image sensor.

### DETAILED DESCRIPTION

The present disclosure includes description in reference to the accompanying drawings, in which various examples are shown. As those skilled in the art would realize, the described examples may be modified in various different ways, all without departing from the spirit or scope of the present disclosure.

Descriptions of some well-known parts are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” refers to a relative positioning (e.g., on a first surface of a substrate compared to on a second surface of the substrate), and does not necessarily mean positioned on the upper side of an object based on a gravitational direction.

In addition, unless explicitly described to the contrary, the word “comprise”, and variations such as “comprises” or “comprising”, will be understood to permit the inclusion of stated elements but not the exclusion of any other elements.

Further, in the specification, the phrase “on a plane” means viewing the object portion from the top, and the phrase “on a cross-section” means viewing a cross-section of which the object portion is vertically cut from the side.

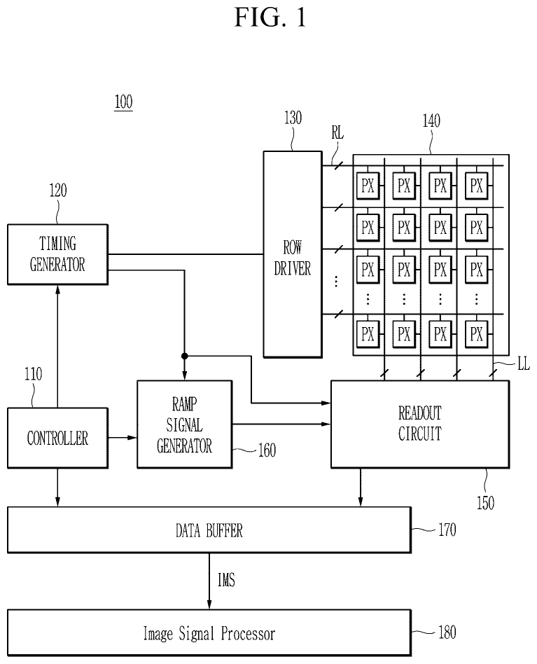

FIG. 1 is a block diagram of an example of an image sensor.

Referring to FIG. 1, an image sensor 100 may include a controller 110, a timing generator 120, a row driver 130, a pixel array 140, a read-out circuit 150, a lamp signal generator 160, a data buffer 170, and an image signal processor 180. In some implementations, the image signal processor 180 may be positioned outside the image sensor 100.

The image sensor 100 may convert light received from the outside into an electric signal to generate an image signal. An image signal IMS may be provided to the image signal processor 180.

The image sensor 100 may be mounted on an electronic device having an image or light sensing function. For example, the image sensor 100 may be mounted on electronic devices such as a camera, a smart phone, a wearable device, an Internet of Things (IoT) device, a home appliance, a tablet personal computer (PC), a personal digital Assistant (PDA), a portable multimedia player (PMP), a navigation, a drone, an advanced driver assistance system (ADAS), and the like. As another example, the image sensor 100 may be mounted on an electronic device provided as a component in a vehicle, a furniture, a manufacturing equipment, a door, or various measuring instruments.

The controller 110 may overall control each component 120, 130, 150, 160, and 170 included in the image sensor 100. The controller 110 may also control the operation timing of each component 120, 130, 150, 160, and 170 by using control signals. In some implementations, the controller 110 may receive a mode signal indicating an imaging mode from an application processor, and may control the image sensor 100 overall based on the received mode signal. For example, the application processor may determine the imaging mode of the image sensor 100 based on various scenarios such as an illumination of an imaging environment, a resolution setting of a user, and a sensed or learned status, and provide the determined result to the controller 110 as a mode signal. The controller 110 may control a plurality of pixels of pixel array 140 to output the pixel signal according to the imaging mode, the pixel array 140 may output the pixel signal for each of the plurality of pixels or the pixel signal for some of the plurality of pixels, and the read-out circuit 150 may sample and process the pixel signal received from the pixel array 140. The timing generator 120 may generate a signal that serves as a reference for the operation timing of the components of the image sensor 100. The timing generator 120 may control the timing of the row driver 130, the read-out circuit 150, and the lamp signal generator 160. The timing generator 120 may provide control signals to control the timing of the row driver 130, the read-out circuit 150, and the lamp signal generator 160.

The pixel array 140 may include a plurality of pixels PX, and a plurality of row lines RL and a plurality of column lines LL, each connected to the plurality of pixels PX. In some implementations, each pixel PX may include at least one or more photoelectric conversion devices. The photoelectric conversion device may detect an incident light and convert the incident light into an electric signal according to the amount of light, that is, a plurality of analog pixel signals. The photoelectric conversion device may be a photodiode, a pin diode, etc. Additionally, the photoelectric conversion device may be a single-photon avalanche diode (SPAD) applied to a 3D sensor pixel. The level of the analog pixel signal output from the photoelectric conversion device may be proportional to the amount of charge output from the photoelectric conversion device. For example, the level of the analog pixel signal output from the photoelectric conversion device may be determined according to the amount of light received within the pixel array 140.

The plurality of row lines RL may extend in the first direction and be connected to the pixels PX arranged along the first direction. For example, the control signal output from the row driver 130 to the row line RL may be transmitted to the gates of the transistors of the plurality of pixels PX connected to the corresponding row line RL. The column line LL may extend in the second direction intersecting the first direction and be connected to the pixels PX arranged along the second direction. The plurality of pixel signals output from the plurality of pixel PX can be transmitted to the read-out circuit 150 through a plurality of column lines LL.

A color filter layer and a micro lens layer may be positioned on the pixel array 140. The micro lens layer includes a plurality of micro lenses, and each of the plurality of micro lenses may be positioned on at least one corresponding pixel PX. The color filter layer may include color filters such as red, green, and blue, and may additionally include a white color filter. For one pixel PX, the color filter of one color may be positioned between the pixel PX and the corresponding micro lens.

The row driver 130 may generate a control signal for driving the pixel array 140 in response to the control signal of the timing generator 120 and provide the control signal to the plurality of pixels PX of the pixel array 140 through the plurality of row lines RL. In some implementations, the row driver 130 may control the pixel PX to detect the incident light by a row line unit. The row line unit may include at least one row line RL. For example, the row driver 130 may provide a transmission signal TS, a reset signal RS, a selection signal SEL, etc. to the pixel array 140 as described below.

The read-out circuit 150 may convert the pixel signal (or the electric signal) from the pixels PX connected to the selected row lines RL among the plurality of pixels PX into a pixel value representing a light quantity, in response to the control signal from the timing generator 120. The read-out circuit 150 may convert the pixel signal output through the corresponding column lines LL into the pixel value. For example, the read-out circuit 150 may convert the pixel signal into the pixel value by comparing the lamp signal and the pixel signal. The pixel value may be an image data having a plurality of bits. For example, the read-out circuit 150 may include a selector, a plurality of comparators, and a plurality of counter circuits.

The lamp signal generator 160 may generate a reference signal and transmit it to the read-out circuit 150.

The lamp signal generator 160 may include a current source, a resistor, and a capacitor. The lamp signal generator 160 may generate a plurality of lamp signals that rise or fall with a slope determined by a current size of a variable current source or a resistance value of a variable resistor by controlling the ramp voltage, which is the voltage applied to the lamp resistor, by controlling the current size of the variable current source or the resistance value of the variable resistor.

The data buffer 170 may store the pixel values of the plurality of pixels PX connected to the selected column lines LL, which are transmitted from the read-out circuit 150, and output the stored pixel values in response to an enable signal from the controller 110.

The Image signal processor 180 may perform the image signal processing on the image signals received from the data buffer 170. For example, the image signal processor 180 may receive the plurality of image signals from the data buffer 170 and synthesize the received image signals to generate one image.

In some implementations, the plurality of pixels may be grouped in a format of M*N (M and N are integers greater than or equal to 2) to form a single unit pixel group. The M*N format may be a format in which M items are listed in the arrangement direction of the column lines LL and N items are listed in the arrangement direction of the row lines RL. For example, one unit pixel group includes a plurality of pixels arranged in a 2*2 format, and one unit pixel group may output one analog pixel signal. The scope of this disclosure is not limited to the case of a single pixel, but may also be applied to the unit pixel group.

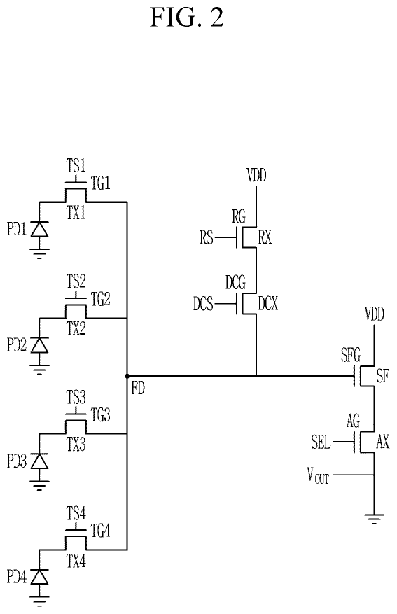

FIG. 2 is a circuit diagram of one pixel included in an example of an image sensor.

Referring to FIG. 2, one pixel may include a plurality of photoelectric conversion devices PD1, PD2, PD3, and PD4. Each of the photoelectric conversion devices PD1, PD2, PD3, and PD4 may perform a photoelectric conversion. As shown in FIG. 2, the plurality of photoelectric conversion devices PD1, PD2, PD3, and PD4 may be connected to a single floating diffusion FD. FIG. 2 illustrates a configuration in which four photoelectric conversion devices are connected to a single floating diffusion FD, but this is only an example, and the number of the photoelectric conversion devices connected to the single floating diffusion FD may vary in various implementations.

The following description focuses on the first photoelectric conversion device PD1, but the following description applies equally to other photoelectric conversion devices PD2, PD3, and PD4.

The first photoelectric conversion device PD1 may generate and accumulate charges according to the amount of light received. The first photoelectric conversion device PD1 may include an anode connected to a ground and a cathode connected to one terminal of the first transmitting transistor TX1. The first transmitting signal TS1 may be supplied to the gate TG1 of the first transmitting transistor TX1, and one terminal of the first transmitting transistor TX1 may be connected to the floating diffusion FD. When the first transmitting transistor TX1 is turned on by the first transmitting signal TS1, the charge stored in the first photoelectric conversion device PD1 may be transmitted to the floating diffusion FD. The floating diffusion FD may retain the charge transmitted from the photoelectric conversion device PD.

Each of the plurality of transmitting transistors TX1, TX2, TX3, and TX4 may include a gate electrode TG1, TG2, TG3, and TG4 connected between one of the plurality of photoelectric conversion devices PD1, PD2, PD3, and PD4 and the floating diffusion FD and receiving a plurality of transmitting signals TS1, TS2, TS3, and TS4). For example, the first transmitting transistor TX1 may include a gate electrode TG1 connected between the first photoelectric conversion device PD1 and the floating diffusion FD and receiving the first transmitting signal TS1. The number of the plurality of transmitting transistors TX1, TX2, TX3, and TX4 may be equal to the number of the plurality of photoelectric conversion devices PD1, PD2, PD3, and PD4.

The reset transistor RX may include a gate electrode RG that is connected between a power source voltage VDD and the floating diffusion FD and receives the reset signal RS.

The reset transistor RX may periodically reset the charges accumulated in the floating diffusion FD. The drain electrode of the reset transistor RX may be connected to the source electrode of a dual conversion transistor (DCX), and the source electrode can be connected to the power source voltage VDD. When the reset transistor RX is turned on, the power source voltage VDD connected to the source electrode of the reset transistor RX may be applied to the floating diffusion FD. Therefore, when the reset transistor RX is turned on, the charges accumulated in the floating diffusion FD may discharged, so that the floating diffusion FD may be reset.

The dual conversion transistor DCX may include a gate electrode DCG that is positioned between the reset transistor RX and the floating diffusion FD and receives the dual conversion signal DCS. The dual conversion transistor DCX may reset the floating diffusion FD together with the reset transistor RX.

The drain electrode of the dual conversion transistor DCX may be connected to the floating diffusion FD, and the source electrode of the dual conversion transistor DCX may be connected to the drain electrode of the reset transistor RX. When the reset transistor RX and the dual conversion transistor DCX are turned on, the power source voltage VDD connected to the source electrode of the reset transistor RX may be applied to the floating diffusion FD through the dual conversion transistor DCX. Therefore, the charges accumulated in the floating diffusion FD may be discharged and the floating diffusion FD may be reset.

The amplifying transistor SF may output the pixel signal according to the voltage of the floating diffusion FD. The gate SFG of the amplifying transistor SF may be connected to the floating diffusion FD, the power source voltage VDD may be supplied to the source electrode of the amplifying transistor SF, and the drain electrode of the amplifying transistor SF may be connected to one end of the selection transistor AX. The amplifying transistor SF may constitute a source follower circuit and output a voltage corresponding to the charge accumulated in the floating diffusion FD as a pixel signal.

When the selection transistor AX is turned on by the selection signal SEL, the pixel signal from the amplifying transistor SF may be transmitted to the read-out circuit. The selection signal SEL may be applied to the gate electrode AG of the selection transistor AX, and the drain electrode of the selection transistor AX may be connected to the output wire Vout that outputs the plurality of pixel signals.

Referring to FIG. 2, the operation of the image sensor is described as follows. First, in a light-blocked state, the power source voltage VDD is applied to the drain electrode of the reset transistor RX and the drain electrode of the amplifying transistor SF, and the reset transistor RX and the dual conversion transistor DCX are turned on to release the charges remaining in the floating diffusion FD. Next, when the reset transistor RX is turned off and an external light is incident on the photoelectric conversion devices PD1, PD2, PD3, and PD4, electron-hole pairs are generated in each of the photoelectric conversion devices PD1, PD2, PD3, and PD4. Holes migrate to and accumulate in the p-type impurities region of the photoelectric conversion devices PD1, PD2, PD3, and PD4, while electrons migrate to and accumulate in the n-type impurities region. When the transmitting transistors TX1, TX2, TX3, and TX4 are turned on, these charges such as electrons and holes are transferred to the floating diffusion FD and accumulated. The gate bias of the amplifying transistor SF changes in proportion to the amount of accumulated charge, which causes the change in the source potential of the amplifying transistor SF. At this time, when the selection transistor AX is turned on, a signal due to the charge is read through the output wire Vout.

A wire may be electrically connected to at least one of the gate electrodes TG1, TG2, TG3, and TG4 of the transmitting transistors TX1, TX2, TX3, and TX4, the gate electrode SFG of the amplifying transistor SF, the gate electrode DCG of the dual conversion transistor DCX, the gate electrode RG of the reset transistor RX, and the gate electrode AG of the selection transistor AX. The wire may include a power voltage transmitting wire that applies the power source voltage VDD to the source electrode of the reset transistor RX or the source electrode of the amplifying transistor SF. The wire may include an output wire Vout connected to the selection transistor AX.

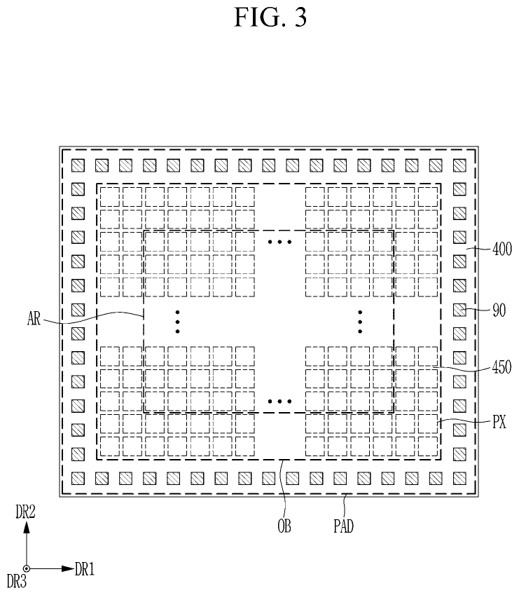

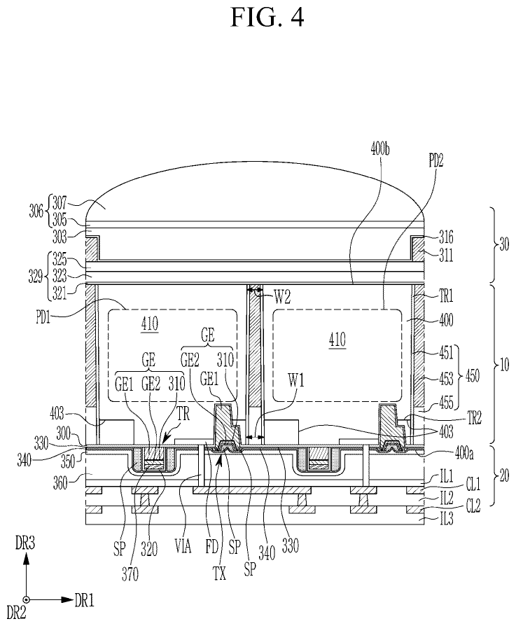

FIG. 3 is a top plan view showing an example of an image sensor. FIG. 4 is a cross-sectional view illustrating a portion of a cross-section of an example of a pixel PX of an image sensor. However, the descriptions in FIG. 3 and FIG. 4 are examples, and the scope of the present disclosure is not limited thereto.

Referring simultaneously to FIG. 3 and FIG. 4, the image sensor may include a photoelectric conversion layer 10, a first wire region 20, and a light transmitting layer 30. The photoelectric conversion layer 10 may include a substrate 400, an isolation pattern 450, an element isolation pattern 403, and a photoelectric conversion region 410 positioned within the substrate 400. Light incident from the outside may be converted into an electrical signal in the photoelectric conversion region 410.

Referring to FIG. 3, the substrate 400 may include a pixel array region AR, an optical black region OB, and a pad region PAD on a planar surface. The pixel array region AR may be positioned in the central region of the substrate 400 on a plane. The pixel array region AR may include the plurality of pixels PX. The pixel PX may output a photoelectric signal from the incident light. The pixel PX may be arranged along a row parallel to the first direction DR1 and a column parallel to the second direction DR2. The pixel PX may include a plurality of photoelectric conversion regions.

The pad region PAD is positioned at the edge of the substrate 400 and may surround the pixel array region AR. A plurality of pad terminal 90 may be positioned in the pad region PAD. The pad terminals 90 may output electrical signals generated in the pixel PX to the outside. As another example, an external electrical signal or voltage may be transmitted to the pixel PX through the pad terminal 90. Since the pad region PAD is positioned at the edge of the substrate 400, the pad terminal 90 may be easily connected to the outside.

The optical black region OB may be placed between the pixel array region AR and the pad region PAD of the substrate 400. The optical black region OB may surround the pixel array region AR. A pixel positioned in the optical black region OB may include a dummy region instead of the photoelectric conversion region 410. The signal generated in the dummy region may be used as an information to remove a process noise.

Below, the stacking structure of the image sensor is described in detail with reference to FIG. 4,.

The substrate 400 may include a first surface 400a and a second surface 400b facing to each other. Light may be incident on the second surface 400b of the substrate 400. The first wire region 20 may be positioned on the first surface 400a of the substrate 400, and the light transmitting layer 30 may be positioned on the second surface 400b of the substrate 400. The substrate 400 may be a semiconductor substrate or a silicon on insulator (SOI) substrate. For example, the semiconductor substrate may include a silicon substrate, a germanium substrate, or a silicon-germanium substrate. The substrate 400 may include an impurity of a first conductivity type. For example, the first conductivity type impurities may be p-type impurities such as aluminum (Al), boron (B), indium (In), and gallium (Ga).

The substrate 400 may include the isolation pattern 450. The isolation pattern 450 may partition a plurality of unit pixels and a plurality of photoelectric conversion regions within one pixel. FIG. 4 shows a portion of a cross-section of one pixel, showing two photoelectric conversion regions on the cross-section. However, this is a virtual cross-section for better understanding and ease of explanation and the present disclosure is not limited to this. That is, as shown in FIG. 2, one pixel can contain four photoelectric conversion regions, and the number of the photoelectric conversion regions included in one pixel may vary.

The substrate 400 may include the photoelectric conversion region 410. The photoelectric conversion region 410 may perform the same function and role as the photoelectric conversion devices PD1, PD2, PD3, and PD4 illustrated in FIG. 2. FIG. 4 shows a first photoelectric conversion device PD1 and a second photoelectric conversion device PD2.

The photoelectric conversion region 410 may be a region doped with a second conductivity type impurity within the substrate 400. The impurity of the second conductivity type may have a conductivity type opposite to the impurity of the first conductivity type. The impurities of the second conductivity type may be n-type impurities such as phosphorus, arsenic, bismuth and antimony. For example, each photoelectric conversion region 410 may include a first region adjacent to the first surface 400a and a second region adjacent to the second surface 400b. There may be a difference in the impurity concentration between the first region and the second region of the photoelectric conversion region 410. Therefore, the photoelectric conversion region 410 may have a potential slope between the first surface 400a and the second surface 400b of the substrate 400. However, as another example, the photoelectric conversion region 410 may not have a potential slope between the first surface 400a and the second surface 400b of the substrate 400.

The substrate 400 and the photoelectric conversion region 410 may form a photodiode. For example, the photodiode may be formed by a p-n junction between the substrate 400 of the first conductivity type and the photoelectric conversion region 410 of the second conductivity type. The photoelectric conversion region 410 constituting the photodiode may generate and accumulate photocharges in proportion to the intensity of the incident light.

Referring to FIG. 4, the isolation pattern 450 may be positioned on the substrate 400. The isolation pattern 450 on a plane may have a lattice structure. While partitioning each pixel on a plane, the isolation pattern 450 may be also positioned between the plurality of photoelectric conversion devices PD1, PD2, PD3, and PD4 included in the single pixel.

Referring to FIG. 4, the isolation pattern 450 may be positioned within the first trench TR1. The first trench TR1 may be recessed from the first surface 400a of the substrate 400. The isolation pattern 450 may extend from the first surface 400a of the substrate 400 toward the second surface 400b. The isolation pattern 450 may be a deep trench isolation (DTI) film. The isolation pattern 450 may penetrate the substrate 400. The vertical height of the isolation pattern 450 may be substantially the same as the vertical thickness of the substrate 400. For example, the width of the isolation pattern 450 may gradually decrease from the first surface 400a of the substrate 400 to the second surface 400b. The width at the first surface 400a of isolation pattern 450 may be a first width W1, and the width at the second surface 400b of the isolation pattern 450 may be a second width W2. For example, the first width W1 may be larger than the second width W2.

The isolation pattern 450 may include a first isolation pattern 451, a second isolation pattern 453, and a capping pattern 455. The first isolation pattern 451 may be positioned along the sidewall of the first trench TR1. The first isolation pattern 451 may include, for example, a silicon-based insulating material (e.g., silicon nitride, silicon oxide or silicon oxidation nitride) or a high-dielectric material (e.g., hafnium oxide or aluminum oxide). As another example, the first isolation pattern 451 may include a plurality of layers, each of which may include different materials. The first isolation pattern 451 may have a lower refractive index than the substrate 400. Accordingly, a crosstalk phenomenon between the photoelectric conversion regions respectively positioned on the substrate 400 may be prevented or reduced.

The second isolation pattern 453 may be positioned within the first isolation pattern 451. For example, the sidewall of the second isolation pattern 453 may be surrounded by the first isolation pattern 451. The first isolation pattern 451 may be positioned between the second isolation pattern 453 and the substrate 400. The second isolation pattern 453 may be separated from the substrate 400 by the first isolation pattern 451. Accordingly, when the image sensor operates, the second isolation pattern 453 may be electrically isolated from the substrate 400. The second isolation pattern 453 may include a crystalline semiconductor material, for example, a polycrystalline silicon. For example, the second isolation pattern 453 may further include a dopant, and the dopant may include an impurity of the first conductivity type or an impurity of the second conductivity type.

For example, the second isolation pattern 453 may include a doped polycrystalline silicon. As another example, the second isolation pattern 453 may include an undoped crystalline semiconductor material. For example, the second isolation pattern 453 may include an undoped polycrystalline silicon. The term “undoped” means that no intentional doping process has been performed. The dopant may include an n-type dopant and a p-type dopant.

The capping pattern 455 may be positioned on the lower surface of the second isolation pattern 453. The capping pattern 455 may be positioned adjacent to the first surface 400a of the substrate 400. The capping pattern 455 may include a non-conductive material. As an example, the capping pattern 455 may include a silicon-based insulating material (e.g., silicon nitride, silicon oxide or silicon oxidation nitride) or a high-dielectric material (e.g., hafnium oxide or aluminum oxide). Accordingly, the isolation pattern 450 may prevent photocharges generated by the incident light incident on the photoelectric conversion region from being incident on another adjacent photoelectric conversion region due to a random drift. That is, the isolation pattern 450 may prevent a crosstalk phenomenon between the photoelectric conversion regions.

The element isolation pattern 403 may be positioned within the substrate 400. For example, the element isolation pattern 403 may be positioned within the second trench TR2. The second trench TR2 may be recessed from the first surface 400a of the substrate 400. The element isolation pattern 403 may be a shallow trench isolation (STI) film. The upper surface of the element isolation pattern 403 may be positioned within the substrate 400. The width of the element isolation pattern 403 may gradually decrease from the first surface 400a of the substrate 400 to the second surface 400b. The upper surface of the element isolation pattern 403 may be vertically separated from the photoelectric conversion region 410. The isolation pattern 450 may overlap a part of the element isolation pattern 403. The element isolation pattern 403 may include a same material as the first isolation pattern 451 of the isolation pattern 450, in which case the boundary between element isolation pattern 403 and first isolation pattern 451 may not be recognized. However, this is only an example, and the scope of the present disclosure is not limited to this configuration.

FIG. 4 illustrates a configuration in which the element isolation pattern 403, the isolation pattern 450, and the first surface 400a of the substrate 400 are positioned on the same plane, but this is only an example, and the pattern arrangement is not limited thereto. For example, the element isolation pattern 403, the isolation pattern 450 and the first surface 400a of substrate 400 may not be coplanar. For example, the element isolation pattern 403 and the isolation pattern 450 may be positioned protruding or sunken from the first surface 400a of the substrate 400.

Also, in FIG. 4, the upper surface of the element isolation pattern 403 and the upper surface of the isolation pattern 450 are depicted as flat, but this is only an example, and the upper surface of element isolation pattern 403 and the upper surface of isolation pattern 450 may include curved surfaces.

Referring to FIG. 4, the transistor TR and the transmitting transistor TX may be positioned on the first surface 400a of the substrate 400. The transmitting transistor TX illustrated in FIG. 4 may be one of the first transmitting transistor TX1, the second transmitting transistor TX2, the third transmitting transistor TX3, and the fourth transmitting transistor TX4 described in FIG. 2. Additionally, the transistor TR illustrated in FIG. 4 may be one of the reset transistor RX, the dual conversion transistor DCX, the amplifying transistor SF, and the selection transistor AX illustrated in FIG. 2. Although not shown in FIG. 4, one or more of the reset transistor RX, the dual conversion transistor DCX, the amplifying transistor SF, or the selection transistor AX may be positioned on the first surface 400a of the substrate 400.

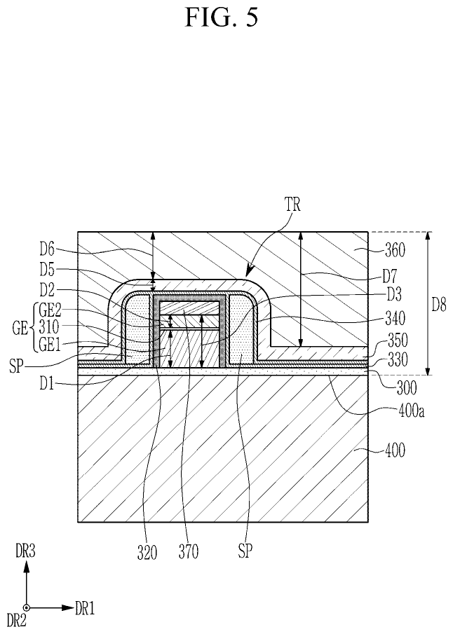

FIG. 5 is an enlarged view of the transistor TR of FIG. 4. Referring to FIG. 5, the first insulation layer 300 may be positioned on the substrate 400. The gate electrode GE may be positioned on the first insulation layer 300. The gate electrode GE may include a first portion GE1 and a second portion GE2. An interlayer oxide layer 310 may be positioned between the first portion GE1 and the second portion GE2. A gate oxide layer 370 may be positioned on the second portion GE2 of the gate electrode GE. As will be explained separately later, the gate oxide layer 370 may be a region formed when a portion of the gate electrode GE is oxidized during the formation process of the gate electrode GE. The first portion GE1 and the second portion GE2 may include polycrystalline silicon.

Referring to FIG. 5, the second insulation layer 320 may be arranged surrounding the gate electrode GE. The second insulation layer 320 may include silicon oxide, but is not limited thereto.

A third insulation layer 330 may be positioned on the second insulation layer 320. The third insulation layer 330 may include silicon oxide, but is not limited thereto. A great spacer SP may be positioned above the third insulation layer 330 and on the side of the gate electrode GE. The gate spacer SP may include silicon nitride, silicon carbonization nitride or silicon oxidation nitride. However, these materials are examples, and the present disclosure is not limited to this.

Additionally, a fourth insulation layer 340 covering the gate spacer SP may be positioned. The fourth insulation layer 340 may include silicon oxide, but is not limited thereto. A fifth insulation layer 350 may be positioned on the fourth insulation layer 340. The fifth insulation layer may include silicon nitride. However, this material is an example and the present disclosure is not limited to this.

A sixth insulation layer 360 may be positioned on the fifth insulation layer 350. The sixth insulation layer 360 may include tetraethyl orthosilicate, but is not limited thereto. The sixth insulation layer 360 may planarize the upper region of the gate electrode GE.

As described above, the first insulation layer 300, the second insulation layer 320, the third insulation layer 330, the fourth insulation layer 340, the fifth insulation layer 350, and the sixth insulation layer 360 may include an insulating material. Examples thereof may include silicon nitride, silicon oxide or silicon oxidation nitride, tetraethyl orthosilicate, etc., but are not limited thereto.

However, the illustrated configuration of the first insulation layer 300, the second insulation layer 320, the third insulation layer 330, the fourth insulation layer 340, the fifth insulation layer 350, and the sixth insulation layer 360 is an example, and one or more of these insulation layers may be omitted in various implementations. In addition, if one or more insulation layers among the first insulation layer 300, the second insulation layer 320, the third insulation layer 330, the fourth insulation layer 340, the fifth insulation layer 350, and the sixth insulation layer 360 include a same material, they may be connected as one without the boundary therebetween being recognized.

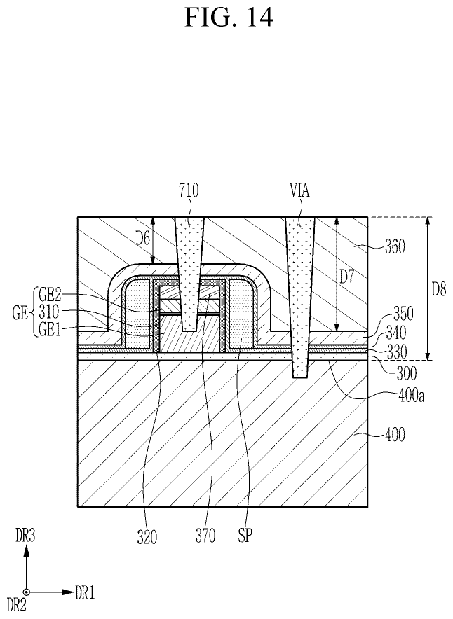

Referring to FIG. 5, in some implementations, the image sensor advantageously exhibits a reduction in the entire thickness D3 of the gate electrode GE. In some image sensors, the thickness of the gate electrode GE may be from about 800 Å to about 1300 Å. In this case, when the thickness of the gate electrode GE is increased, as will be explained separately in reference to FIG. 14, the entire thickness D8 of the insulation layer through which a through-contact 710 and a via connecting the gate electrode GE and the wire pass increases, which causes a parasitic capacitance and may reduce a SNR (signal to noise ratio) of the image sensor.

However, in the forming process of the gate electrode GE, if the gate electrode is formed to be less than 800 Å, there may be a challenge that the gate electrode is oxidized in the subsequent process, which makes the thickness that actually operates as the gate electrode thinner and reduces the device reliability. Therefore, it is challenging to form the gate electrode GE with the thickness of less than 800 Å.

However, according to some implementations of the present disclosure, the gate electrode GE exhibits a reduced entire thickness D3 of the gate electrode GE based on deposition of the first portion GE1 and the second portion GE2 of the gate electrode GE in separate processes. For example, referring to FIG. 5, the entire thickness D3 of the gate electrode GE may be 400 Å to 500 Å. For example, the thickness D1 of the first portion GE1 of the gate electrode GE may be 360 Å to 440 Å. Additionally, the thickness of the second portion GE2 of the gate electrode GE may be 40 Å to 70 Å. The interlayer oxide layer 310 may be positioned between the first portion GE1 and the second portion GE2. This may be an oxide layer that occurs naturally during the process, since the first portion GE1 and the second portion GE2 are each formed through separate processes.

Both the first portion GE1 and the second portion GE2 may include polycrystalline silicon. As will be explained separately later, the second portion GE2 may be formed as amorphous silicon and be crystallized into polycrystalline silicon through heat treatment in a subsequent process.

Referring to FIG. 5, the thickness D5 of the fifth insulation layer 350 may be 450 Å to 550 Å. However, this is only an example and the thickness is not limited to now.

Also, referring to FIG. 5, the thickness of the sixth insulation layer 360 may vary from region to region. In some implementations, the sixth insulation layer 360 may include tetraethyl orthosilicate. The sixth insulation layer 360 may planarize the upper region of the first surface 400a of the substrate 400 on which the gate electrode GE is formed. Therefore, the sixth insulation layer 360 may have different thicknesses between the portion that overlaps the gate electrode GE and the portion that does not overlap. Referring to FIG. 5, the thickness D6 of the portion of the sixth insulation layer 360 that overlaps the gate electrode of the sixth insulation layer 360 may be 450 Å to 550 Å. Additionally, the thickness D7 of the portion of the sixth insulation layer 360 that does not overlap the gate electrode may be 1000 Å to 1100 Å.

For example, the thickness of the sixth insulation layer 360 may be affected by the thickness of the gate electrode GE. In order to stably form through-hole contacts (referring, e.g., to 710 in FIG. 14) in the gate electrode GE in subsequent processes, it may be advantageous for the thickness of the sixth insulation layer 360 positioned above the gate electrode GE to be 500 Å or more. Therefore, for the planarization, the thickness of the sixth insulation layer 360, which does not overlap the gate electrode GE, may be the sum of the thickness D3 of the gate electrode GE and the target minimum thickness of 500 Å of the insulation layer positioned above the gate electrode GE. Therefore, in order to reduce the thickness of the sixth insulation layer 360, it may be advantageous to reduce the thickness of the gate electrode GE.

Accordingly, in some implementations of image sensors described herein, the gate electrode GE includes the first portion GE1, the second portion GE2, and the interlayer oxide layer 310 positioned between the first portion GE1 and the second portion GE2. By dividing the gate electrode GE into the first portion GE1 and the second portion GE2, the entire thickness of the gate electrode GE may be formed thinly, from 400 Å to 500 Å. An example of a specific manufacturing method will be described separately later.

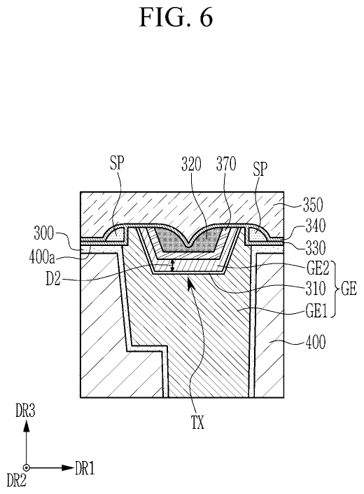

FIG. 6 is an enlarged view of an example of a transmitting transistor TX shown in FIG. 4. Referring to FIG. 6, the transmitting transistor TX may be formed by the same process as the transistor TR illustrated in FIG. 5, and thus may have a similar stacking structure. Referring to FIG. 6, the gate electrode GE of the transmitting transistor TX may include a first portion GE1, a second portion GE2, and an interlayer oxide layer 310 positioned between the first portion GE1 and the second portion GE2. In some implementations, the first portion GE1 of the gate electrode GE may be positioned at least partially within the substrate 400.

Referring to FIG. 6, one or more regions or portions of the upper surface of the gate electrode GE of the transmitting transistor TX may be positioned lower (from the perspective shown in FIG. 6) than the first surface 400a of the substrate 400. For example, as shown in FIG. 6, the gate electrode GE of the transmitting transistor TX may have a concave upper surface in the direction toward the second surface 400b of the substrate 400 (from the perspective shown in FIG. 6).

As shown in FIG. 6, one or more regions or portions of the second portion GE2 of the gate electrode GE may be positioned below the first surface 400a of the substrate 400 (from the perspective shown in FIG. 6). This may be because, as explained above, the gate electrode GE of the image sensor is formed with a relatively thin thickness, and the material of the gate electrode GE of the transmitting transistor TX may not completely fill the trench of the substrate 400. For example, when the gate electrode GE of the transistor TR is formed to be relatively thick, the gate electrode GE of the transmitting transistor TX formed by the same process may be formed by filling the trench formed in the substrate 400 and protruding onto the first surface 400a of the substrate 400. However, in some implementations, when the gate electrode GE of the transistor TR is formed to be relatively thin (e.g., a thickness of 400 Å to 500 Å), the gate electrode GE of the transmitting transistor TX formed by the same process does not completely fill the trench formed in the substrate 400, and may have a U-shaped upper surface, as shown in FIG. 6.

In the transistor illustrated in FIG. 6, the thickness D2 of the second portion GE2 of the gate electrode GE may be 40 Å to 70 Å. For example, in the transistor illustrated in FIG. 5 and the transistor illustrated in FIG. 6, the thickness of the second portion GE2 of the gate electrode GE may be the same.

Referring to FIG. 6, characteristics of the first insulation layer 300, the second insulation layer 320, the third insulation layer 330, the fourth insulation layer 340, and the fifth insulation layer 350 in the gate electrode GE of the transmitting transistor TX are the same as or similar to those described in FIG. 5. The specific descriptions of the same components are omitted. In FIG. 6, the sixth insulation layer is omitted, but in some implementations the sixth insulation layer may be positioned on the fifth insulation layer 350 for the transistor of FIG. 6..

In the gate electrode GE illustrated in FIG. 5 and FIG. 6, the first insulation layer 300, the second insulation layer 320, the third insulation layer 330, the fourth insulation layer 340, the fifth insulation layer 350, and the sixth insulation layer 360 may be formed by the same process and include the same material. However, this is an example, and the scope of the present disclosure is not limited to this.

Referring again to FIG. 4, the first wire region 20 may be positioned on the first surface 400a of the substrate 400 and may include a plurality of insulation layers IL1, IL2, and IL3, a plurality of wiring layers CL1, and CL2, and a via VIA.

The insulation layer may include a first insulation layer IL1, a second insulation layer IL2 and a third insulation layer IL3.

The first insulation layer IL1 may cover the first surface 400a of the substrate 400. In FIG. 4, the sixth insulation layer 360 and the first insulation layer IL1 are depicted as separate configurations, but in some implementations the sixth insulation layer 360 and the first insulation layer IL1 may have the same configuration. For example, the sixth insulation layer 360 described above may form the first insulation layer IL1.

The second insulation layer IL2 may be positioned on the first insulation layer IL1. The third insulation layer IL3 may be positioned on the second insulation layer IL2.

The first insulation layer to the third insulation layer IL1, IL2, and IL3 may include a non-conductive material. For example, the first insulation layer to the third insulation layer IL1, IL2, and IL3 may include a silicon-based insulating material such as silicon oxide, silicon nitride or silicon oxidation nitride.

The first wire region 20 may include a first wiring layer CL1 and a second wiring layer CL2. The first wiring layer CL1 may be positioned within the second insulation layer IL2. The second wiring layer CL2 may be positioned within the third insulation layer IL3.

A plurality of vias VIA may be positioned in the first insulation layer IL1, second insulation layer IL2, and the third insulation layer IL3. The via may connect the floating diffusion FD, the first wiring layer CL1 and the second wiring layer CL2.

The first wiring layer CL1, the second wiring layer CL2 and the via VIA may include a metallic material. For example, the first wiring layer CL1, the second wiring layer CL2, and the vias VIA may include copper (Cu).

In some implementations, the image sensor may include a light transmitting layer 30. The light transmitting layer 30 may include an insulating structure 329, a color filter 303 and a micro lens part 306. The light transmitting layer 30 may collect and filter light incident from the outside and provide the light to the photoelectric conversion region 410.

The color filter 303 may be positioned on the second surface 400b of the substrate 400. The color filter 303 may be placed on each pixel PX. In each pixel PX, the color filter 303 may include primary color filters. The color filter 303 may include a first color filter, a second color filter, and a third color filter having different colors. For example, the first color filter, the second color filter, and the third color filter may each include green, red, and blue color filters. The first color filter, the second color filter, and the third color filter may be arranged in a Bayer pattern. As another example, the first color filter, the second color filter, and the third color filter may include colors such as cyan, magenta, or yellow.

An insulating structure 329 may be positioned between the second surface 400b of the substrate 400 and the color filter 303. The insulating structure 329 may prevent a reflection of light so that light incident on the second surface 400b of the substrate 400 may smoothly reach the photoelectric conversion region 410. The insulating structure 329 may be named as an antireflection structure.

The insulating structure 329 may include a first fixing charge layer 321, a second fixing charge layer 323, and a planarization layer 325 sequentially stacked on the second surface 400b of the substrate 400. The first fixing charge layer 321, the second fixing charge layer 323, and the planarization layer 325 may respectively include different materials. The first fixing charge layer 321 may include any one of aluminum oxide, tantalum oxide, titanium oxide, or hafnium oxide. The second fixing charge layer 323 may include any one of aluminum oxide, tantalum oxide, titanium oxide, or hafnium oxide. For example, the first fixing charge layer 321 may include aluminum oxide, the second fixing charge layer 323 may include hafnium oxide, and the planarization layer 325 may include silicon oxide. In some implementations, a silicon anti-reflection layer may be interposed between the second fixing charge layer 323 and the planarization layer 325. The anti-reflection layer may include silicon nitride.

The micro lens part 306 may be positioned on the color filter 303. The micro lens part 306 may include a flat portion 305 in contact with the color filter 303 and a micro lens 307 positioned on the flat portion 305.

The flat portion 305 may, for example, include an organic material. As another example, the flat portion 305 may include silicon oxide or silicon oxidation nitride. The micro lens 307 may have a convex shape to focus incident light. Each micro lens 307 may vertically overlap the photoelectric conversion region 410. The shape of the lens may vary. FIG. 4 shows, for better comprehension and ease of description, the shape that one micro lens 307 overlaps two photoelectric conversion regions 410 in a cross-section. However, on a plane, one micro lens 307 may be positioned in a shape that overlaps four photoelectric conversion regions 410. However, this is just an example, and the number of the micro lenses 307 positioned on one pixel PX may vary in various implementations.

The light transmitting layer 30 may further include a Bayer pattern 311 and a passivation layer 316. The Bayer pattern 311 may be positioned between adjacent color filters 303 to separate them from each other. The Bayer pattern 311 may be positioned on the insulating structure 329. For example, the Bayer pattern 311 may have a lattice structure. The Bayer pattern 311 may include materials having a lower refractive index than color filter 303. The Bayer pattern 311 may include an organic material. For example, the Bayer pattern 311 may be a polymer layer including silica nano particles. The Bayer pattern 311 has a low refractive index, which may increase the amount of light incident on the photoelectric conversion region 410 and reduce a crosstalk between the pixels PX. That is, a light receiving efficiency may be increased in each photoelectric conversion region 410, and the signal noise ratio (SNR) characteristic may be improved.

The passivation layer 316 may cover the surface of the Bayer pattern 311 with the substantially uniform thickness. The passivation layer 316 may include, for example, a single film or multilayer of at least one of an aluminum oxide layer and a silicon carbonization oxide layer. The passivation layer 316 may protect the color filter 303 and perform a moisture absorption function.

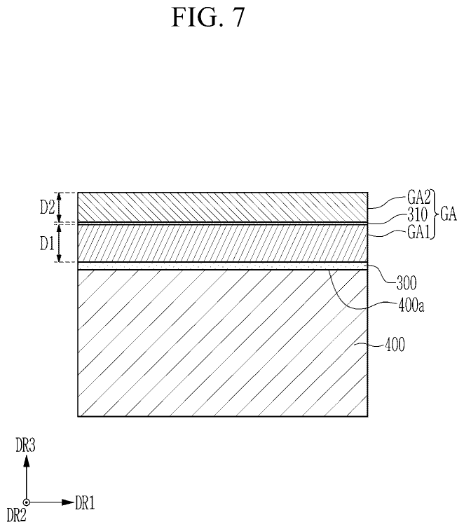

An example of a manufacturing method of an image sensor is described below. FIG. 7 to FIG. 14 are process cross-sectional views showing an example of a manufacturing method of an image sensor. The manufacturing method is described with a focus on the forming process of the transistor TR. However, it will be understood that the method is also applicable to forming other image sensor structures, e.g., the transistor TX.

Referring to FIG. 7, a first insulation layer 300 is formed on a substrate 400. However, the formation of the first insulation layer 300 is only an example and the scope of the present disclosure is not limited thereto.

Referring to FIG. 7, a first gate conductive layer GA1 is formed on the first insulation layer 300. The first gate conductive layer GA1 may include polycrystalline silicon. The thickness D1 of the first gate conductive layer GA1 formed at this time may be 360 Å to 440 Å. In some implementations, the thickness D1 of the first gate conductive layer GA1 may be 400 Å.

Next, a second gate conductive layer GA2 is formed on the first gate conductive layer GA1. The second gate conductive layer GA2 may include amorphous silicon. The second gate conductive layer GA2 may be formed with a thinner thickness than the first gate conductive layer GA1. For example, the thickness D2 of the second gate conductive layer GA2 may be 90 Å to 110 Å. Since the second gate conductive layer GA2 is formed after the first gate conductive layer GA1 is formed in this way, an interlayer oxide layer 310 may be formed between the first gate conductive layer GA1 and the second gate conductive layer GA2.

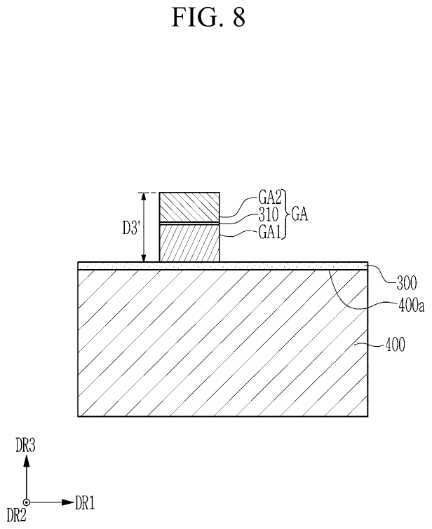

Next, referring to FIG. 8, the first gate conductive layer GA1 and the second gate conductive layer GA2 are etched to form a gate electrode structure GA. At this time, the thickness D3′ of the gate electrode structure GA may be 450 Å to 550 Å. As will be explained separately later, the thickness of the gate electrode actually manufactured through the subsequent process may be thinner than the thickness D3′ of the gate electrode structure GA formed in this step.

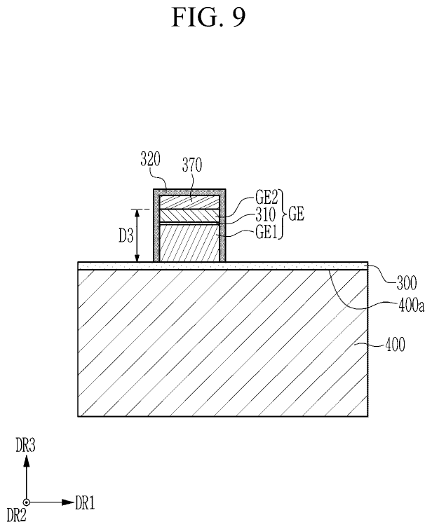

Next, referring to FIG. 9, a second insulation layer 320 is formed surrounding the gate electrode GE. The second insulation layer 320 may include silicon oxide, but is not limited thereto. A heat treatment process may be performed during the process of forming the second insulation layer 320. During this process, the amorphous silicon of the second gate conductive layer GA2 may be crystallized to become polycrystalline silicon. However, not all of the entire region of the second gate conductive layer GA2 stacked in the previous step becomes polycrystalline silicon, but some of it may be oxidized to become a gate oxide layer 370. In this stage, the second gate conductive layer GA2 may be formed by the second portion GE2 of the gate electrode GE and the gate oxide layer 370. The portion where amorphous silicon is crystallized may form the second portion GE2 of the gate electrode GE, and the portion where amorphous silicon is oxidized may form the gate oxide layer 370. The gate oxide layer 370 is an insulation layer and does not function as a gate electrode. Therefore, as shown in FIG. 9, the gate electrode GE formed in this step may include a first portion GE1, an interlayer oxide layer 310, and a second portion GE2. Since some regions of the second gate conductive layer GA2 become the gate oxide layer 370, the thickness D3 of the gate electrode GE may be thinner than the thickness D3′ of the gate electrode structure GA in the previous step. At this stage, the thickness D3 of the gate electrode GE may be 400 Å to 500 Å.

As shown in FIGS. 5 and 9, a planar shape of the gate oxide layer 370 (e.g., in a plan view) may match a planar shape of the second portion GE2. For example, the gate oxide layer 370 and the second portion GE2 may have matching widths and be substantially entirely aligned with one another, substantially entirely overlapping one another.

In the process of forming the gate electrode material and forming the insulation layer surrounding the gate electrode, a portion of the gate electrode may be oxidized to become the insulation layer. Therefore, when forming the gate electrode thinly, a significant portion of the gate electrode may be oxidized and become the insulation layer, presenting challenges because achieving a stable contact between the gate electrode and the through-hole contact may be difficult thereafter. For example, when the thickness of the gate electrode is formed to 800 Å and the insulation layer is formed, there may be a challenge in that a significant portion of the gate electrode, for example, a region larger than 150 Å, is oxidized during the process step, which reduces the thickness of the portion that actually functions as the gate electrode. Therefore, it is challenging to form the gate electrode thinly below a certain thickness.

However, in some implementations of image sensors described herein, the gate electrode is divided and stacked into the first portion GE1 and the second portion GE2, and the second portion GE2 is formed of amorphous silicon. In the process step, some regions of the second portion GE2 are oxidized, thereby preventing the first portion GE1 from being oxidized. In other words, what is oxidized is the portion of the second portion GE2, which is amorphous silicon, and the first portion GE1 is not oxidized (substantially not oxidized), so even if the gate electrode is formed thinly, the gate electrode may operate stably.

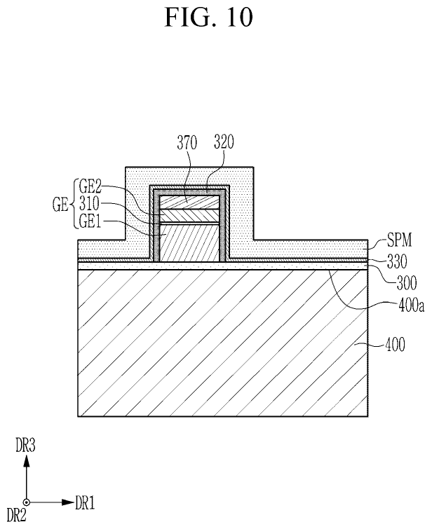

Next, referring to FIG. 10, a third insulation layer 330 and a spacer material SPM are deposited on the entire surface. The third insulation layer 330 may protect the lower structure from being etched together during the subsequent etching process of the spacer material SPM. The third insulation layer 330 may include silicon oxide.

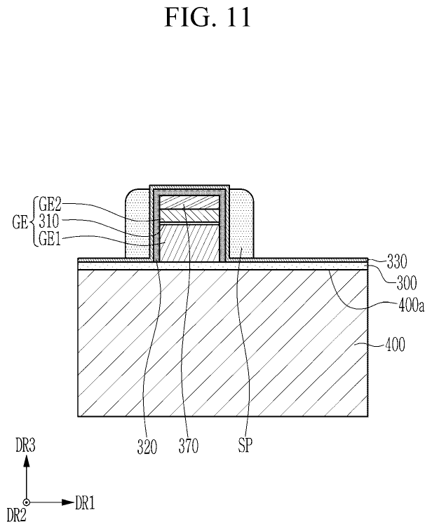

Next, referring to FIG. 11, the spacer SP is formed by etching the spacer material SPM. As shown in FIG. 11, the spacer SP may be formed along the sidewall of the gate electrode GE.

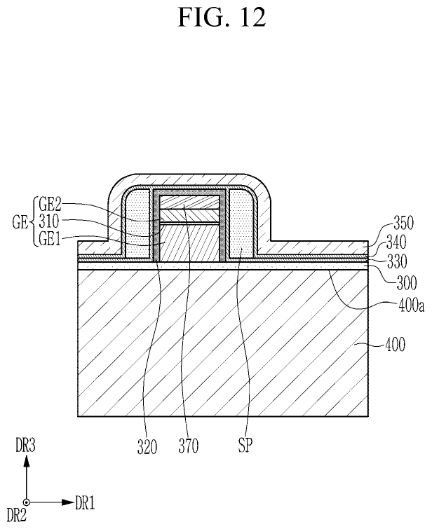

Referring to FIG. 12 below, a fourth insulation layer 340 and a fifth insulation layer 350 are formed on the spacer SP and the gate electrode GE. The fourth insulation layer 340 may include silicon oxide, and the fifth insulation layer 350 may include silicon nitride, but are not limited thereto. The fourth insulation layer 340 and the fifth insulation layer 350 may be omitted in some implementations.

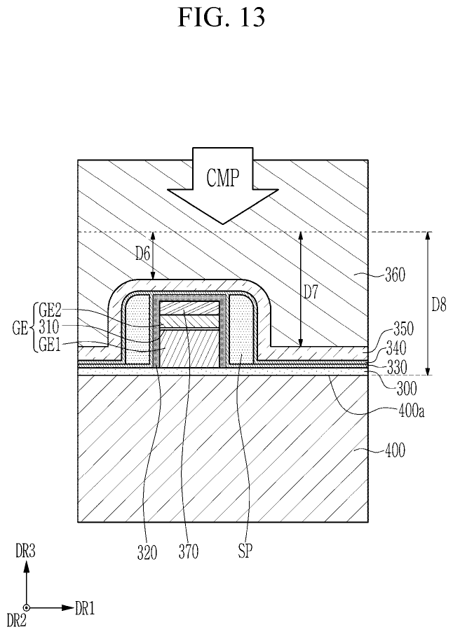

Next, referring to FIG. 13, a sixth insulation layer 360 is formed. The sixth insulation layer 360 may be a planarization layer that flattens the upper portion of the region where the gate electrode GE is formed. The sixth insulation layer 360 may include tetraethyl orthosilicate. Referring to FIG. 13, the sixth insulation layer 360 may be formed thickly and then etched by a CMP process. As shown in FIG. 13, after etching, the sixth insulation layer 360 may have different thicknesses in the portion that overlaps the gate electrode GE and the portion that does not overlap it. Referring to FIG. 13, the thickness D6 of the portion that overlaps the gate electrode among the sixth insulation layer 360 may be 450 Å to 550 Å. Additionally, the thickness D7 of the portion that does not overlap the gate electrode may be 1000 Å to 1100 Å. By forming the thickness of the sixth insulation layer 360 differently for each region, the upper surface of the gate electrode GE may be planarized.

Next, referring to FIG. 14, a through-hole contact 710 and a via VIA are formed. Referring to FIG. 14, the through-hole contact 710 may penetrate the gate electrode GE and the insulation layer on the upper side of the gate electrode GE to be in contact with the first portion GE1 of the gate electrode GE. However, this is just an example, and the through-hole contact 710 may also be in contact with the second portion GE2 of the gate electrode GE. Additionally, the via VIA may penetrate the insulation layer in the region where the gate electrode GE is not formed and be in contact with a floating diffusion region positioned on the substrate 400.

At this time, the entire thickness D8 of insulation layers through which the via VIA passes (e.g., to reach the substrate 400) may be 1500 Å to 1700 Å. As explained above, the gate electrode GE is formed thinly, from 400 Å to 500 Å, which shortens the distance through which the via connected to the floating diffusion passes. Therefore, a conversion gain of the image sensor may be increased. If the insulation layer on the floating diffusion is formed thickly, the signal to noise ratio (SNR) may decrease due to a parasitic capacitance. However, as described herein, by forming the thickness of the gate electrode thinly, the entire thickness of the insulation layer may be formed thinly, thereby reducing the parasitic capacitance and increasing the conversion gain of the image sensor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. An image sensor comprising:
a substrate including a photoelectric conversion region, wherein the substrate comprises a first surface and a second surface facing in opposite directions; and
a first transistor and a second transistor positioned on the first surface of the substrate,
wherein the first transistor comprises a first gate electrode, and wherein the first gate electrode comprises:
a first portion,
a second portion, and
an interlayer oxide layer between the first portion and the second portion,
wherein a thickness of the first gate electrode is in a range from 400 Å to 500 Å and the upper surface of the gate electrode of the second transistor includes a region that is depressed in a direction toward the second surface of the substrate.

2. The image sensor of claim 1, wherein the first portion of the first gate electrode is between the interlayer oxide layer and the first surface of the substrate, and
wherein a thickness of the first portion of the first gate electrode is greater than a thickness of the second portion of the first gate electrode.

3. The image sensor of claim 2, wherein the thickness of the first portion of the first gate electrode is in a range from 360 Å to 440 Å, and
wherein the thickness of the second portion of the first gate electrode is in a range from 40 Å to 70 Å.

4. The image sensor of claim 1, further comprising:
a gate oxide layer positioned on the second portion of the gate electrode of the first transistor, and
the planar shape of the gate oxide layer is the same as the planar shape of the second portion of the gate electrode of the first transistor.

5. The image sensor of claim 1, wherein:
the second gate electrode includes:
a third portion,
a fourth portion, wherein the third portion is closer to the second surface of the substrate than is the fourth portion, and
a second interlayer oxide layer between the third portion and the fourth portion,
wherein the third portion of the second gate electrode is arranged at least partially within the substrate.

6. The image sensor of claim 5, wherein:
the first surface of the substrate comprises an upper surface of the substrate, and
a portion of the fourth portion of the second gate electrode is below the first surface of the substrate.

7. The image sensor of claim 5, wherein a thickness of the fourth portion of the second gate electrode is in a range from 40 Å to 70 Å.

8. The image sensor of claim 4, wherein:
the first transistor is one of a reset transistor, a dual conversion transistor, an amplifying transistor, or a selection transistor, and
the second transistor is a transmitting transistor.

9. The image sensor of claim 1, wherein the first portion and the second portion of the first gate electrode each comprise polycrystalline silicon.

10. The image sensor of claim 1, wherein the first surface of the substrate comprises an upper surface of the substrate, and wherein the image sensor comprises:
a planarization layer on an upper surface of the first transistor,
wherein a greatest thickness of the planarization layer is in a range from 1000 Å to 1100 Å.

11. An image sensor comprising:
a substrate including a photoelectric conversion region; and
a first transistor and a second transistor positioned on a first surface of the substrate, wherein the first surface comprises an upper surface of the substrate,
wherein the first transistor comprises a first gate electrode, wherein the first gate electrode comprises:
a first portion,
a second portion, and
a first interlayer oxide layer between the first portion and the second portion,
wherein a thickness of the first gate electrode is in a range from 400 Å to 500 Å,
wherein the second transistor comprises a second gate electrode, wherein the second gate electrode comprises:
a third portion,
a fourth portion, and
a second interlayer oxide layer between the third portion and the fourth portion, and
wherein at least a portion of each of the third portion and the fourth portion are positioned below the first surface of the substrate.

12. The image sensor of claim 11, further comprising:
an insulation layer on the second gate electrode,
wherein an upper surface of the insulation layer includes a concave portion.

13. The image sensor of claim 11, wherein:
the first portion of the first gate electrode is between the second portion of the first gate electrode and the first surface of the substrate,
the third portion of the second gate electrode is closer to a second surface of the substrate than is the fourth portion of the second gate electrode, wherein the second surface faces opposite to the first surface,
a thickness of the first portion is greater than a thickness of the second portion, and
a thickness of the third portion is greater than a thickness of the fourth portion.

14. The image sensor of claim 11, wherein:
the first portion of the first gate electrode is between the second portion of the first gate electrode and the first surface of the substrate,
a thickness of the first portion of the first gate electrode is in a range from 360 Å to 440 Å, and
a thickness of the second portion of the first gate electrode is in a range from 40 Å to 70 Å.

15. The image sensor of claim 11, wherein:
the third portion of the second gate electrode is closer to a second surface of the substrate than is the fourth portion of the second gate electrode, wherein the second surface faces opposite to the first surface, and
a thickness of the fourth portion is in a range from 40 Å to 70 Å.

16. The image sensor of claim 11, comprising:
a gate oxide layer on the second portion of the first gate electrode, and
an insulation layer on the first gate electrode and the gate oxide layer.

17. An image sensor comprising:
a substrate comprising a photoelectric conversion region; and
a first transistor and a second transistor on a first surface of the substrate,
wherein the first transistor comprises a first gate electrode, wherein the first gate electrode comprises:
a first portion,
a second portion, and
a first interlayer oxide layer between the first portion and the second portion,
wherein a thickness of the first gate electrode is in a range from 400 Å to 500 Å,
wherein a thickness of the first portion is greater than a thickness of the second portion,
wherein the second transistor comprises a second gate electrode, wherein the second gate electrode comprises:
a third portion,
a fourth portion, and
a second interlayer oxide layer between the third portion and the fourth portion, and
wherein a thickness of the third portion is greater than a thickness of the fourth portion.

18. The image sensor of claim 17, wherein:
the first surface comprises an upper surface of the substrate, and
an upper surface of the second gate electrode is arranged at least partially lower than the first surface of the substrate.

19. The image sensor of claim 17, wherein:
an upper surface of the second gate electrode includes a concave portion.

20. The image sensor of claim 17, wherein:
a thickness of the first portion of the first gate electrode is in a range from 360 Å to 440 Å, and
a thickness of the second portion of the first gate electrode is in a range from 40 Å to 70 Å.
